(19) United States
(12) Patent Application Publication
(10) Pub. No.: US 2025/0301540 A1
(43) Pub. Date: Sep. 25, 2025

(54) Induction Hob

(71) Applicant: Guangdong Willing Technology Corporation, Huizhou (CN)

(72) Inventors: Jingnong Ye, Huizhou (CN); Shifa Luo, Huizhou (CN); Jiulong Wang, Huizhou (CN)

(21) Appl. No.: 18/748,177

(22) Filed: Jun. 20, 2024

(30) Foreign Application Priority Data
Mar. 22, 2024 (CN) 202410333990.4

(51) Int. Cl. H05B 6/06; H05B 1/02; H05B 6/12

(52) U.S. Cl. CPC H05B 6/062; H05B 1/0266; H05B 6/1209; H05B 2206/022; H05B 2213/07

(57) ABSTRACT

Disclosed in the present disclosure is an induction hob, including a bottom housing, a top housing, a glass front panel provided sequentially from bottom to top. A movable support that moves up and down is provided, a top of the movable support is provided with a non-ferrous probe, an upper end surface of the non-ferrous probe is protruded from the glass front panel, the movable support that moves up and down ensures that the non-ferrous probe stays in close contact with a bottom of the pan in real time. The temperature sensor is in close contact with the non-ferrous probe, so that heat from the non-ferrous probe is transferable to the temperature sensor, thereby allowing the heat from the pan to be transferred from the non-ferrous probe to the temperature sensor.

### CROSS REFERENCE TO RELATED APPLICATIONS

The present application claims the benefit of Chinese Patent Application No. 202410333990.4 filed on Mar. 22, 2024, the contents of which are incorporated herein by reference in their entirety.

### FIELD

The present disclosure relates to the technical field of induction hobs and, particularly, to an induction hob.

### BACKGROUND

Induction hobs are common household appliances in daily life, which heat pans by electromagnetic induction, thereby enabling them to be used for cooking meals.

The deficiency of the prior art is that the induction hob is unable to detect the real-time temperature of the pan, which results in the induction hob not being able to accurately control or regulate the cooking temperature of the pan, which causes a certain degree of annoyance to the cooking of the user.

### SUMMARY

An objective of the present disclosure is to provide an induction hob to solve a technical problem in the prior art in which the induction hob is unable to detect the real-time temperature of a pan, which results in the induction hob not being able to accurately control or regulate the cooking temperature of the pan, causing a certain degree of annoyance to the cooking of the user.

To achieve the aforementioned purpose, provided by the technical solution of the present disclosure is an induction hob, including a bottom housing, a top housing, and a glass front panel provided sequentially from bottom to top, in which: a movable support that moves up and down is provided in the bottom housing, the movable support is provided with an elastic member that enables the movable support to move up and down, a top of the movable support is provided with a non-ferrous probe, the top housing is provided with an opening, the glass front panel is provided with an assembly hole, the non-ferrous probe slides through the opening and the assembly hole sequentially from inside to outside, an upper end surface of the non-ferrous probe is protruded from the glass front panel, the induction hob further comprises a control board, a temperature sensor electrically connected to the control board is provided in the movable support, and the temperature sensor is in close contact with the non-ferrous probe and is capable of transferring heat.

Further, an insulating sheet is provided between the temperature sensor and the non-ferrous probe, both the temperature sensor and the non-ferrous probe are in close contact with the insulating sheet, so that heat from the non-ferrous probe is transferable through the insulating sheet to the temperature sensor.

Further, an interior of the movable support is provided with a columnar assembly channel, the temperature sensor is mounted in the assembly channel, and the insulating sheet is covered on a top surface of the assembly channel.

Further, the movable support is further provided with a temperature fuse, the temperature fuse is electrically connected to an externally supplied power line, the insulating sheet is provided between the temperature fuse and the non-ferrous probe, both the temperature fuse and the non-ferrous probe are in close contact with the insulating sheet, so that heat from the non-ferrous probe is transferable through the insulating sheet to the temperature fuse.

Further, an interior of the movable support is provided with a fuse mounting groove, the temperature fuse is mounted in the fuse mounting groove, and a bottom of the fuse mounting groove is provided with a skeletonized structure for dissipating heat from the temperature fuse that is fused.

Further, a soft gel for sealing is attached between an edge of the non-ferrous probe and an inner wall of the assembly hole, the edge of the non-ferrous probe is provided with a sealing groove, an inner ring surface of the soft gel is provided with a sealing ring, the sealing ring is snap-fitted into the sealing groove, an outer ring surface of the soft gel is provided with an inclined annular protrusion part, the assembly hole is provided with a first bevel that expands outward, a second bevel of the annular protrusion part is in close contact with the first bevel, and a soft gel part that is concave inwardly or convex outwardly is provided between the annular protrusion part and the sealing ring.

Further, restricting plates are provided on both sides of a top edge of the movable support respectively, the restricting plates on both sides upwardly support two lateral edges at bottom of the soft gel respectively, two lateral edges at bottom of the non-ferrous probe are provided with restricting openings respectively, and the restricting plates on both sides are in restricted fit with the restricting openings on both sides.

Further, a bottom edge of the non-ferrous probe is in a form of a downwardly extending cylinder, a top edge of the movable support is in a form of an upwardly extending cylinder, and a top of the movable support is sheathed into a bottom of the non-ferrous probe with snap-fit fastening.

Further, a coil support is provided between the bottom housing and the top housing, a shielding layer is provided between the coil support and the bottom housing, a center of the coil support is provided with an active hole, a bottom edge of the movable support is in a form of a downwardly extending cylinder, the bottom housing is provided with a cylindrical chamber extending upwardly, a bottom of the movable support passes through the active hole and is sheathed into a cylindrical chamber of the bottom housing, and the elastic member is elastically pressed against between the bottom of the movable support and the cylindrical chamber of the bottom housing.

Further, the movable support allows a travel of 3 mm+0.5 mm from top to bottom, the elastic member is a spring, the non-ferrous probe is a metallic probe that is non-ferrous, and the temperature sensor is an NTC temperature sensor.

In summary, the technical solutions of the present disclosure provide the beneficial effects as follows:

(1) By providing a movable support that moves up and down, a top of the movable support is provided with a non-ferrous probe, a top housing is provided with an opening, the glass front panel is provided with an assembly hole, and the non-ferrous probe passes through the opening and the assembly hole sequentially from inside to outside, so that the upper end surface of the non-ferrous probe is protruded from the glass front panel. The non-ferrous probe may slide within the opening and the assembly hole, so that the non-ferrous probe is subjected to a downward pressing by the pan and pushes the movable support downwards, and the movable support presses downwards against the elastic member when the pan is placed onto the glass front panel of the induction hob. When the bottom of the pan in contact with the non-ferrous probe is concave upward, the movable support pushes the non-ferrous probe upward under the elastic force of the elastic member to keep close contact with the bottom of the pan, so as to ensure that the non-ferrous probe and the bottom of the pan keep close contact with each other in real time.

(2) By providing a temperature sensor electrically connected to the control board in the movable support, the temperature sensor is in close contact with the non-ferrous probe, so that heat from the non-ferrous probe is transferable to the temperature sensor, thereby allowing the heat from the pan to be transferred from the non-ferrous probe to the temperature sensor. Therefore, the temperature sensor is able to detect a real-time temperature of the pan, and transfers the real-time temperature to the control board, so that the control board may adjust the heating power of the induction hob according thereto. Additionally, the non-ferrous probe stays in close contact with the bottom of the pan, so as to achieve that the induction hob detects the real-time temperature of the pan, which is convenient for the induction hob to accurately control or regulate the temperature of the pan for cooking meals, offering convenience for users to cook meals.

### BRIEF DESCRIPTION OF THE DRAWINGS

FIG. 1 is a schematic structural diagram in a first perspective view of the present invention;

FIG. 2 is a schematic structural diagram in a second perspective view of the present invention;

FIG. 3 is a schematic structural diagram in a perspective view of the glass front panel in the present invention;

FIG. 4 is a schematic structural diagram in a perspective view of the present invention removing the glass front panel;

FIG. 5 is a schematic structural diagram in a perspective view of the top housing in the present invention;

FIG. 6 is a schematic structural diagram in a perspective view of the present invention removing the glass front panel and the top housing;

FIG. 7 is a schematic structural diagram in a perspective view of the coil support in the present invention;

FIG. 8 is a schematic structural diagram in a perspective view of the bottom housing in the present invention removing the coil support;

FIG. 9 is a schematic structural diagram in a first perspective view of the cooperation of the movable support, the non-ferrous probe, and the soft gel in the present invention;

FIG. 10 is a schematic structural diagram in a second perspective view of the cooperation of the movable support, the non-ferrous probe, and the soft gel in the present invention;

FIG. 11 is a schematic structural diagram in a perspective view of the cooperation of the movable support and the non-ferrous probe in the present invention;

FIG. 12 is a schematic structural diagram in a perspective view of the non-ferrous probe in the present invention;

FIG. 13 is a schematic structural diagram in a perspective view of the movable support in the present invention;

FIG. 14 is a schematic structural diagram in a perspective view of the bottom housing in the present invention removing the coil support, the movable support, the non-ferrous probe, and the soft gel;

FIG. 15 is a schematic structural diagram in a perspective section view of the present invention;

FIG. 16 is a schematic partially enlarged diagram of FIG. 15.

Labels: 1 bottom housing; 2 top housing; 3 glass front panel; 4 coil support; 5 movable support; 6 non-ferrous probe; 7 soft gel; 8 insulating sheet; 9 power line; 10 shielding layer; 11 first fan; 12 second fan; 13 heat dissipating sheet; 14 motherboard; 15 control board; 101 cylindrical chamber; 102 air inlet hole; 201 opening; 301 assembly hole; 401 active hole; 501 assembly channel; 502 fuse mounting slot; 503 restricting plate; 601 restricting opening.

### DETAILED DESCRIPTION OF THE EMBODIMENTS

The technical solutions in the embodiments of the present disclosure are clearly and completely described below in conjunction with the accompanying drawings of the present disclosure, but without limiting the scope of the present disclosure.

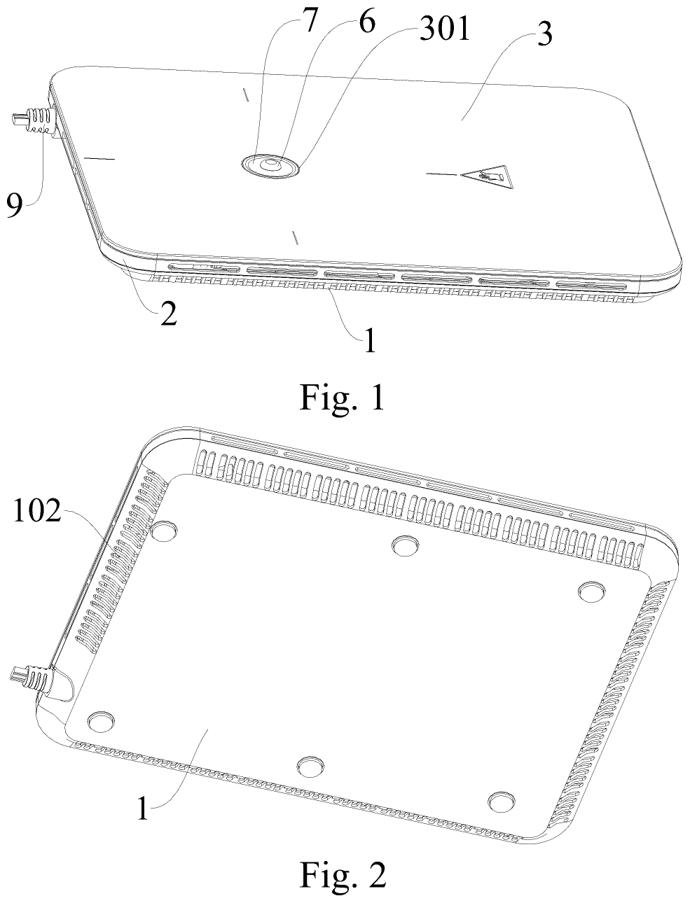

In the present disclosure, for better description, the following illustrations are made: the observer faces the accompanying FIG. 1 for observation, the left side of the observer is set to left, the right side of the observer is set to right, the front of the observer is set to front, the back of the observer is set to back, the top of the observer is set to top, and the bottom of the observer is set to bottom. It should be noted that the terms “front,” “back,” “left,” “right,” “center,” “top,” “bottom,” and the like are used in the text to indicate orientation or positional relationships based on the accompanying drawings only for the purpose of facilitating a clear description of the present disclosure and are not intended to indicate or imply that the structures or parts referred to necessarily have a particular orientation or are constructed in a particular orientation and, therefore, are not to be construed as a limitation of the present disclosure. In addition, the related terms “first”, “second”, “third” and “fourth”, if any, are used only for purposes of clarity or simplicity of description and are not to be construed as indicating or implying relative importance or quantity.

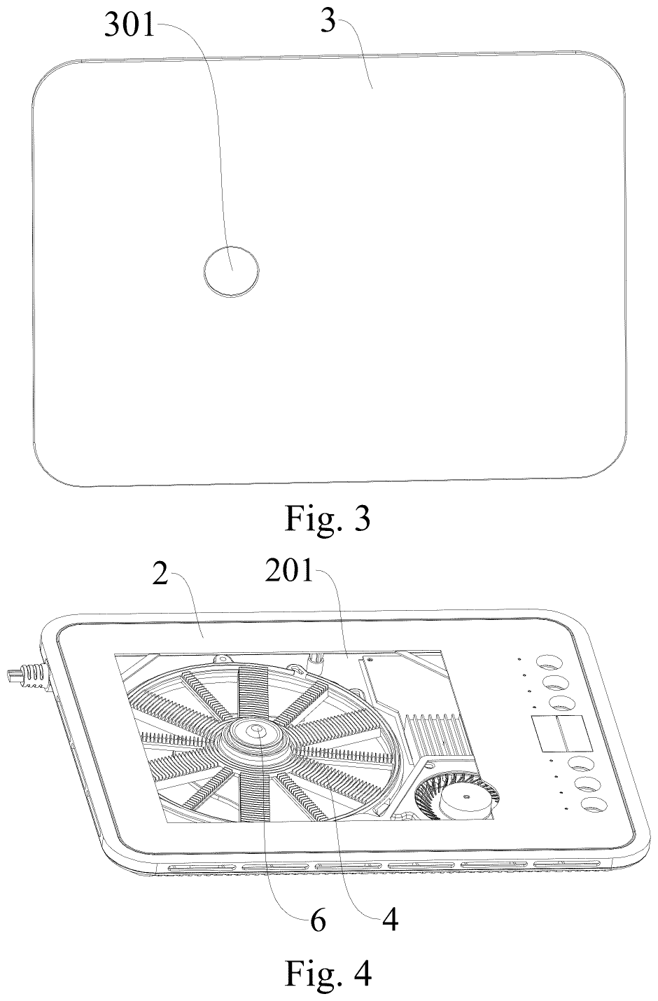

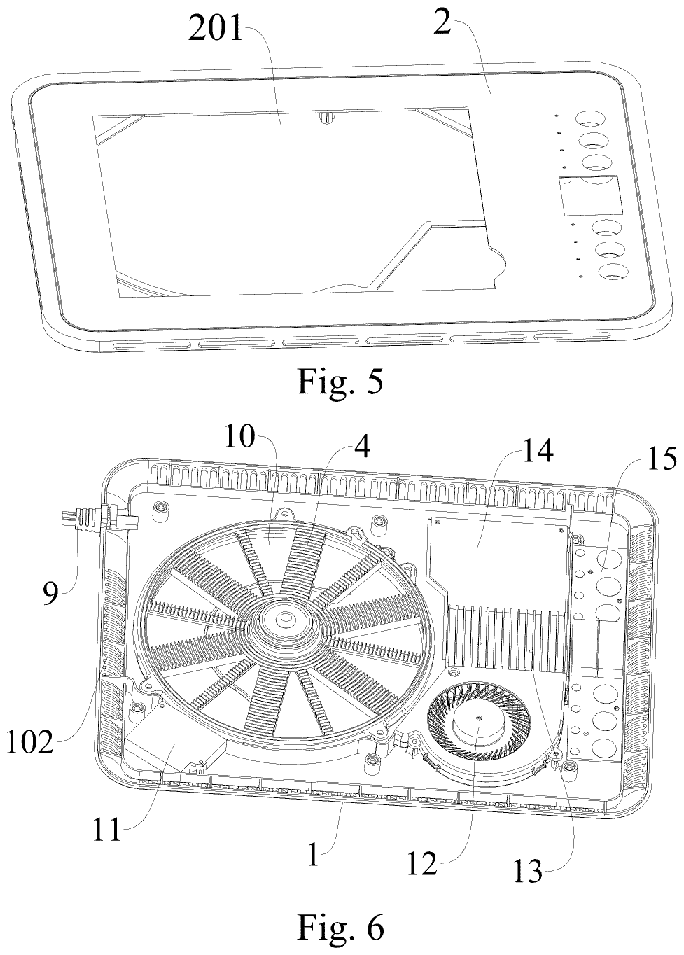

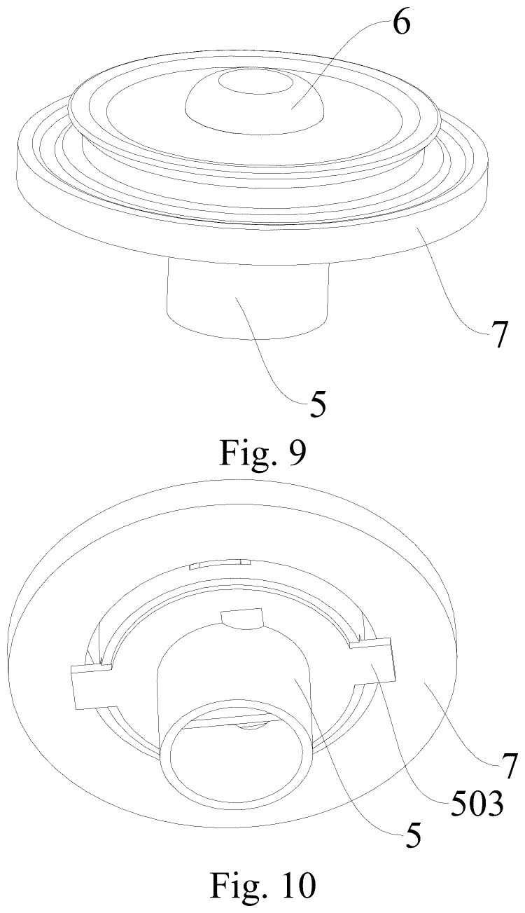

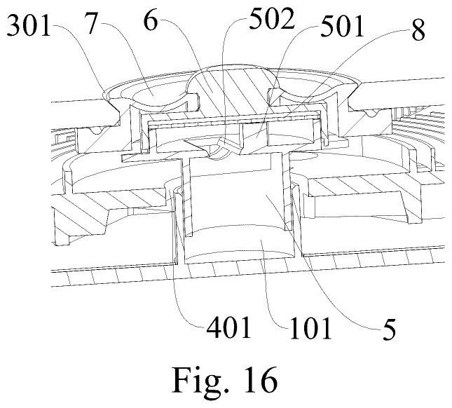

Referring to FIG. 1, provided in the present embodiment is an induction hob, including a bottom housing 1, a top housing 2, and a glass front panel 3 provided sequentially from bottom to top. Referring to FIG. 4, a coil support 4 is provided between the bottom housing 1 and the top housing 2, and the coil support 4 is wound with an electromagnetic coil. Referring to FIG. 9, a center of the coil support 4 is provided with a movable support 5 that moves up and down, a bottom of the movable support 5 is provided with an elastic member, and a top of the movable support 5 is provided with a non-ferrous probe 6. Referring to FIGS. 1, and 3-5, the top housing 2 is provided with an opening 201, the glass front panel 3 is provided with an assembly hole 301, and the non-ferrous probe 6 slides through the opening 201 and the assembly hole 301 sequentially from inside to outside. Referring to FIGS. 1 and 9, a soft gel 7 is attached between an edge of the non-ferrous probe 6 and an inner wall of the assembly hole 301. Referring to FIGS. 14 and 16, a center of the movable support 5 is provided with a temperature sensor, and an insulating sheet 8 is in close contact between the temperature sensor and the non-ferrous probe 6, so that heat from the non-ferrous probe 6 may be transferred through the insulating sheet 8 to the temperature sensor. Effect: (1) By providing the following: the bottom housing 1, the top housing 2, the glass front panel 3 are provided sequentially from bottom to top, the coil support 4 is provided between the bottom housing 1 and the top housing 2, the electromagnetic coil is wound on the coil support 4; therefore, an alternating current may be introduced into the electromagnetic coil when in use, and an alternating magnetic field will be generated around the coil, and most of the magnetic lines of the alternating magnetic field pass through the pan, generating a large number of eddy currents in the bottom of the pan, thereby generating the heat required for cooking. (2) By providing the following: a movable support 5 that moves up and down is provided on the center of the coil support 4, a bottom of the movable support 5 is provided with an elastic member, a top of the movable support 5 is provided with a non-ferrous probe 6, a top housing 2 is provided with an opening 201, the glass front panel 3 is provided with an assembly hole 301, the non-ferrous probe 6 slidably passes through the opening 201 and the assembly hole 301 sequentially from inside to outside, and a soft gel 7 is attached between an edge of the non-ferrous probe 6 and an inner wall of the assembly hole 301; therefore, the non-ferrous probe 6 is subjected to a downward pressing by the pan and pushes the movable support 5 downwards and the movable support 5 presses downwards against the elastic member, when the pan is placed onto the glass front panel 3 of the induction hob. When the bottom of the pan in contact with the non-ferrous probe 6 is concave upward, the movable support 5 pushes the non-ferrous probe 6 upward under the elastic force of the elastic member to keep close contact with the bottom of the pan, so as to ensure that the non-ferrous probe and the bottom of the pan keep close contact with each other in real time. Additionally, the soft gel 7 may achieve waterproof and dustproof. (3) A temperature sensor is provided in the center of the movable support 5, and an insulating sheet 8 is in close contact between the temperature sensor and the non-ferrous probe 6, so that the heat of the non-ferrous probe 6 may be transferred to the temperature sensor through the insulating sheet 8; therefore, the heat of the pan is transferred to the temperature sensor through the non-ferrous probe 6 and the insulating sheet 8 sequentially, so that the temperature sensor may detect the real-time temperature of the pan; additionally, the insulating sheet 8 may satisfy the purpose of insulation to improve safety, and also satisfy the function of thermal conductivity for the temperature sensor to improve the efficiency of real-time thermal conductivity. It is clear from the analysis that, with the non-iron probe 6 always in close contact with the bottom of the pan, the temperature sensor achieves the detection of the real-time temperature of the pan, it facilitates the induction hob to accurately control or regulate the cooking temperature of the pan, and provides convenience to the user for cooking.

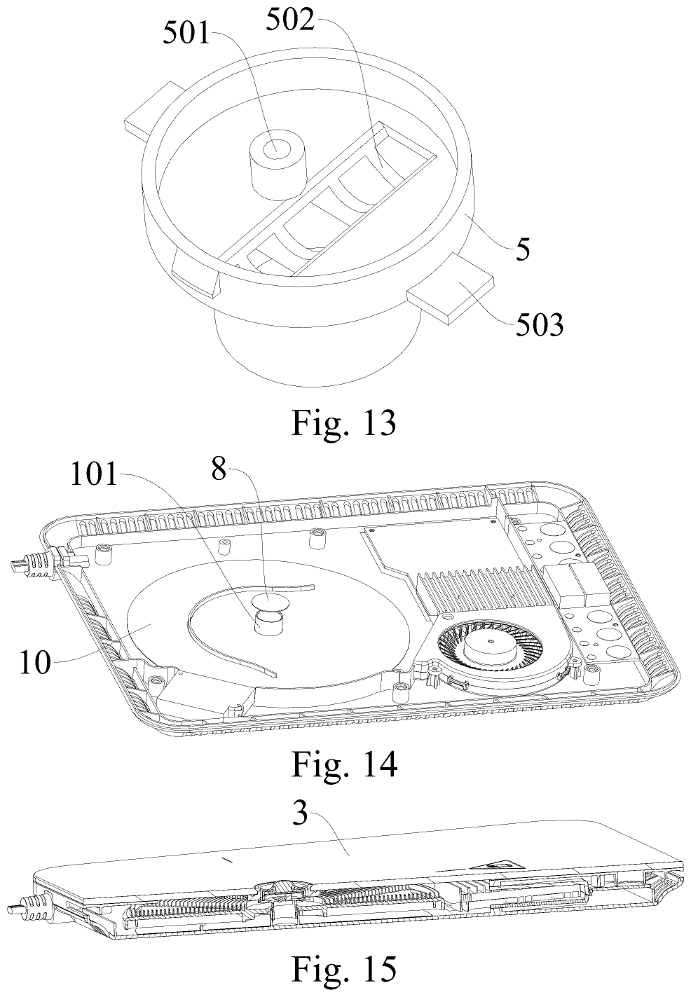

In the present embodiment, referring to FIGS. 6 and 13, a center of the movable support 5 is also provided with a temperature fuse, and the temperature fuse is electrically connected to a power line 9. The insulating sheet 8 is in close contact between the temperature fuse and the non-ferrous probe 6, so that the heat from the non-ferrous probe 6 is transferable to the temperature fuse through the insulating sheet 8. Effect: In the event that the temperature of the pan is too high (exceeding a preset maximum temperature), since the heat of the pan may also be transferred to the temperature fuse sequentially through the non-ferrous probe 6 and the insulating sheet 8, the temperature fuse may fuse when the temperature fuse receives an abnormally large amount of heat from the pan. In doing so, the power line 9 of the induction hob achieves an automatic power off, which protects the other components of the induction hob. Additionally, the insulating sheet 8 may satisfy the purpose of insulation to improve safety, and may satisfy the function of thermal conductivity for the temperature fuse to improve the efficiency of real-time thermal conductivity.

In some implementations, there is another way that the temperature fuse may fuse. The heat of the pan is transferred to the temperature sensor through the non-ferrous probe 6 and the insulating sheet 8 sequentially, and when the temperature sensor receives an abnormally large amount of heat from the pan, the temperature sensor sends a signal to the control system of the induction hob in order to adjust the heating power of the induction hob. If the control system of the induction hob fails to adjust the heating power of the induction hob, the temperature fuse will fuse, so that the power line 9 of the induction hob achieves automatic power off, thereby protecting other components of the induction hob.

In the present embodiment, referring to FIGS. 13 and 16, a center of the movable support 5 is provided with an assembly channel 501 and a fuse mounting groove 502 arranged in parallel, and the temperature sensor and the temperature fuse are mounted in the assembly channel 501 and the fuse mounting groove 502, respectively (not shown in figures). Effect: By setting up the assembly channel 501 and the fuse mounting groove 502, and utilizing the insulating sheet 8 on top to cover the opening at the upper end of the assembly channel 501, the temperature sensor may be effectively separated from the temperature fuse. Since the temperature sensor and the temperature fuse are respectively connected to the weak electricity and the strong electricity, the effective separation may avoid the mutual influence.

Specifically, referring to FIGS. 15-16, the soft gel 7 is attached between a top edge of the non-ferrous probe 6 and an inner wall of the assembly hole 301, a bottom edge of the non-ferrous probe 6 is in a form of a downwardly extending cylinder, a top edge of the movable support 5 is in a form of an upwardly extending cylinder, and a top of the movable support 5 is sheathed into a bottom of the non-ferrous probe 6 with snap-fit fastening. Effect: The soft gel 7 is so set up that it achieves waterproof and dustproof, while the cylindrical bottom of the non-ferrous probe 6 cooperates with the cylindrical top of the movable support 5, so that it facilitates the protection of the temperature sensor and the temperature fuse positioned in the middle, and the snap-fit fixation also facilitates the dismounting and mounting.

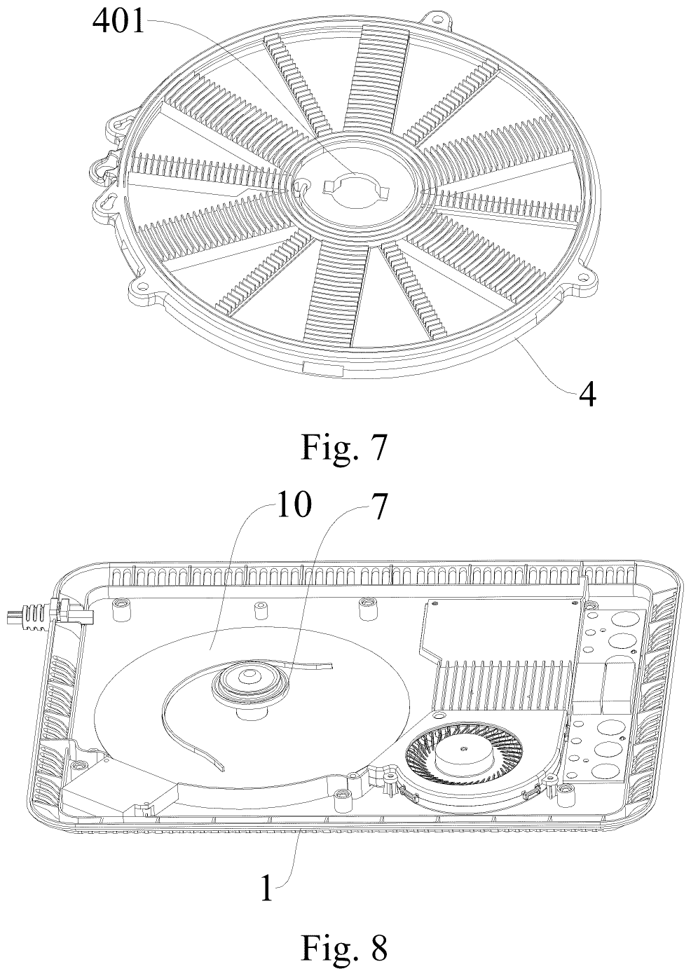

Further, referring to FIGS. 7 and 16, the soft gel 7 is provided with a first sealing ring part and a second sealing ring part which are provided in a stepped shape. The first sealing ring part is positioned at a peripheral part of the second sealing ring part, and in a vertical direction, the second sealing ring part is positioned on top of the first sealing ring part. A middle of the second sealing ring part is provided with a fitting hole, i.e., the inner ring surface, and a sealing ring is provided on an inner wall of the fitting hole. A top surface of the non-ferrous probe is provided with a cylinder protruding upwardly, a top surface of the cylinder is provided with a flange extending externally around the perimeter, and a sealing groove is formed between the flange and the top surface of the non-ferrous probe 6. The assembly hole 301 is provided with a first bevel that gradually expands outwardly from bottom to top, so that the opening of the assembly hole 301 gradually expands outwardly from bottom to top, and the setting of the first bevel on the inner wall of the assembly hole 301 allows an annular protrusion to be formed on a lower part of the inner wall of the assembly hole 301.

When the soft gel 7 is assembled with the non-ferrous probe 6, the cylinder passes through the fitting hole, the sealing ring snaps into the sealing groove, and the second sealing ring part snaps into the assembly hole 301, the second sealing ring part is provided with a second bevel, the first bevel and the second bevel are in close contact with each other, and the annular protrusion snaps into the stepped position between the first sealing ring part and the second sealing ring part. The upper surface of the first sealing ring part is abutted against the bottom surface of the glass front panel 3, and the upper surface of the first sealing ring part is provided with a reservoir, so that a small amount of liquid may be stored in the reservoir after a small amount of liquid permeates into the soft gel 7 via the first bevel and the second bevel, avoiding the liquid from entering into an interior of the circuit.

The outer ring surface of the second sealing ring part is provided with an inclined annular flange, and the second bevel is provided on the annular flange. A soft gel part concave inwardly is provided between the annular flange and the fitting hole. The soft gel part is easy to deform, which facilitates the mounting of the soft gel 7. Moreover, the soft gel part concave inwardly may store a small amount of liquid, preventing the liquid from entering the fitting hole and the assembly hole 301. In addition, the soft gel part concave inwardly allows for sufficient deformability when the non-ferrous probe 6 moves up and down, without breaking the seal of the soft gel 7.

Specifically, referring to FIGS. 7 and 16, a center of the coil support 4 is provided with an active hole 401, a bottom edge of the movable support 5 is in a form of a downwardly extending cylinder, the bottom housing 1 is provided with a cylindrical chamber 101 extending upwardly, a bottom of the movable support 5 passes through the active hole 401 and is sheathed into a cylindrical chamber 101 of the bottom housing 1, and the elastic member is elastically pressed against between the bottom of the movable support 5 and the cylindrical chamber 101 of the bottom housing 1. Effect: By providing the active hole 401, the cylindrical bottom of the movable support 5, and the cylindrical chamber 101 of the bottom housing 1, it facilitates the mounting of the elastic parts and the carrying out of elastic work, so that the movable support 5 is movable upwardly and downwardly.

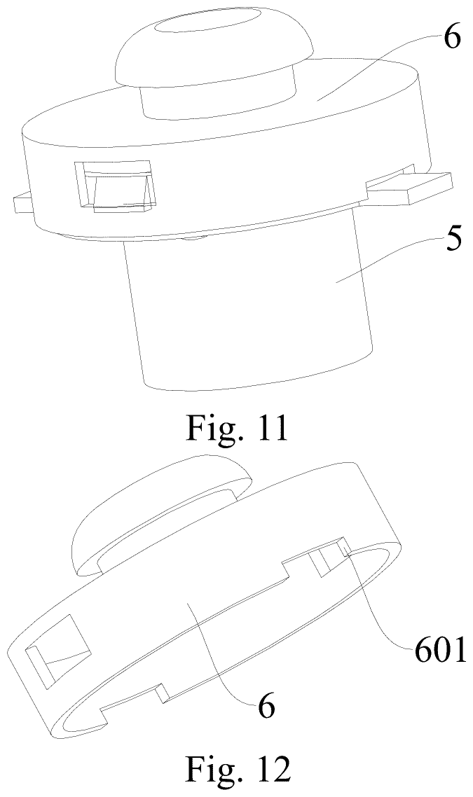

Specifically, referring to FIGS. 10-14, restricting plates 503 are provided on both sides of a top edge of the movable support 5 respectively, the restricting plates 503 on both sides upwardly support two lateral edges at bottom of the soft gel 7 respectively, two lateral edges at bottom of the non-ferrous probe 6 are provided with restricting openings 601 respectively, and the restricting plates 503 on both sides are in restricted fit with the restricting openings 601 on both sides. Effect: By providing the restricting plates 503 on both sides, on the one hand, the restricting plates 503 may support the soft gel 7 upwardly, and on the other hand, the restricting plates 503 and the restricting openings 601 are in restricted cooperation, which may prevent the relative rotation between the non-ferrous probe 6 and the movable support 5, ensuring that the non-ferrous probe 6 is kept stable when it is in operation.

Further, in order to achieve the snap-fit fixation of the movable support 5 and the non-ferrous probe 6, an upper side of the movable support 5 is provided with an outwardly protruding buckle, and a lower side of the non-ferrous probe 6 is provided with a slot, and when the movable support 5 and the non-ferrous probe 6 are snap-fit fastened, the buckle snaps into the slot. Preferably, the slot is a through-hole. When the buckle is snap-fitted into the slot, the restricting plate 503 is snap-fitted into the restricting opening 601.

In the present embodiment, the elastic member is a spring (not shown in figures), the insulating sheet 8 is a ceramic sheet, the non-ferrous probe 6 is a metallic probe that is non-ferrous, the soft gel 7 is a silica gel, and the temperature sensor is an NTC temperature sensor. Effect: The elasticity of the spring, as well as the structure thereof, is better adapted to the up and down movement of the movable support 5. The ceramic sheet allows for good insulation and thermal conductivity, and ceramic sheets may also be used as a double layer of insulation. Non-ferrous metal probe refers to metal probes other than iron probes, as iron probes are susceptible to electromagnetic induction lines and generate a large number of eddy currents to generate heat by themselves, and thermal conductivity thereof is also not good enough, which may easily affect the temperature sensor or temperature fuse to detect the real-time temperature of the pan. Silica gel emits no odor when heated compared to seals made from other materials. The NTC temperature sensor detects well.

In the present embodiment, the movable support 5 allows a travel of 3 mm+0.5 mm from top to bottom, the insulating sheet 8 is made of aluminum oxide or zirconium oxide, and the non-ferrous probe 6 is made of aluminum or copper. Effect: The travel of 3 mm+0.5 mm up and down of the movable support 5 enables the non-ferrous probe 6 to achieve the purpose of being in real-time in contact with the bottom surface of the pan, while the insulating sheet made of aluminum oxide or zirconium oxide is the cost-effective choice among the ceramic sheets, and the probe made of aluminum or copper is the one that provides a better thermal conductivity.

In the present embodiment, referring to FIGS. 6-8, a shielding layer 10 is provided between the coil support 4 and the bottom housing 1, and the bottom housing 1, the top housing 2, and the glass front panel 3 are detachably mounted to each other. Effect: by providing the shielding layer 10, the magnetic lines generated by the electromagnetic coil may be avoided from being emitted downward in large quantities; and the detachable mounting between the bottom housing 1, the top housing 2, and the glass front panel 3 facilitates the mounting and dismounting of the internal parts of the induction hob, in which the glass front panel 3 may be microcrystalline glass.

Specifically, referring to FIGS. 4-6, a first fan 11, a second fan 12, a heat dissipating sheet 13, a motherboard 14, and a control board 15 are provided between the bottom housing 1 and the top housing 2, in which the first fan 11 and the second fan 12 may dissipate heat from the electromagnetic coil on the coil support 4, the second fan 12 may also cooperate with the heat dissipating sheet to dissipate heat from the motherboard 14, and a perimeter of the bottom housing 1 is provided with air inlet holes 102, which may also be referred to FIG. 2. The motherboard 14 is electrically connected to the electromagnetic coil, the temperature sensor, and the control board 15. Effect: The electromagnetic coil on the coil support 4 is cooled by means of the first fan 11 and the second fan 12, thereby avoiding overheating of the electromagnetic coil. The second fan 12 may cooperate with the heat dissipating sheet 13 to strengthen the heat dissipation of the motherboard 14, so as to avoid the overheating of the motherboard 14. Since the motherboard 14 is responsible for controlling the work of the induction hob, there are a great number of chips that generate heat, and it is necessary for the second fan 12 to cooperate with the heat dissipating sheet 13 to strengthen the heat dissipation of the motherboard 14. The perimeter of the bottom housing 1 is provided with air inlet holes 102, which provide sufficient air source for the first fan 11 and the second fan 12. The control board 15 is responsible for human-computer interaction.

In summary, with the non-iron probe 6 always in close contact with the bottom of the pan, the temperature sensor achieves the detection of the real-time temperature of the pan, which facilitates the induction hob to accurately control or regulate the cooking temperature of the pan, and provides convenience to the user for cooking, so that a precisely temperature-controlled and temperature-regulated induction hob is provided by the present disclosure.

The above described is preferred embodiments of the present disclosure. It should be noted that for those skilled in the art, a plurality of improvements and modifications may be made without departing from the principles of the present disclosure, which should also be considered as the scope of protection of the present disclosure.

1. An induction hob, comprising a bottom housing, a top housing, and a glass front panel provided sequentially from bottom to top, wherein a movable support that moves up and down is provided in the bottom housing, the movable support is provided with an elastic member that enables the movable support to move up and down, a top of the movable support is provided with a non-ferrous probe, the top housing is provided with an opening, the glass front panel is provided with an assembly hole, the non-ferrous probe slides through the opening and the assembly hole sequentially from inside to outside, an upper end surface of the non-ferrous probe is protruded from the glass front panel, the induction hob further comprises a control board, a temperature sensor electrically connected to the control board is provided in the movable support, and the temperature sensor is in close contact with the non-ferrous probe and is capable of transferring heat.

2. The induction hob according to claim 1, wherein an insulating sheet is provided between the temperature sensor and the non-ferrous probe, both the temperature sensor and the non-ferrous probe are in close contact with the insulating sheet, so that heat from the non-ferrous probe is transferable through the insulating sheet to the temperature sensor.

3. The induction hob according to claim 2, wherein an interior of the movable support is provided with a columnar assembly channel, the temperature sensor is mounted in the assembly channel, and the insulating sheet is covered on a top surface of the assembly channel.

4. The induction hob according to claim 1, wherein the movable support is further provided with a temperature fuse, the temperature fuse is electrically connected to an externally supplied power line, an insulating sheet is provided between the temperature fuse and the non-ferrous probe, both the temperature fuse and the non-ferrous probe are in close contact with the insulating sheet, so that heat from the non-ferrous probe is transferable through the insulating sheet to the temperature fuse.

5. The induction hob according to claim 4, wherein an interior of the movable support is provided with a fuse mounting groove, the temperature fuse is mounted in the fuse mounting groove, and a bottom of the fuse mounting groove is provided with a skeletonized structure for dissipating heat from the temperature fuse that is fused.

6. The induction hob according to claim 1, wherein a soft gel for sealing is attached between an edge of the non-ferrous probe and an inner wall of the assembly hole, the edge of the non-ferrous probe is provided with a sealing groove, an inner ring surface of the soft gel is provided with a sealing ring, the sealing ring is snap-fitted into the sealing groove, an outer ring surface of the soft gel is provided with an inclined annular protrusion part, the assembly hole is provided with a first bevel that expands outward, a second bevel of the annular protrusion part is in close contact with the first bevel, and a soft gel part that is concave inwardly or convex outwardly is provided between the annular protrusion part and the sealing ring.

7. The induction hob according to claim 2, wherein a soft gel for sealing is attached between an edge of the non-ferrous probe and an inner wall of the assembly hole, the edge of the non-ferrous probe is provided with a sealing groove, an inner ring surface of the soft gel is provided with a sealing ring, the sealing ring is snap-fitted into the sealing groove, an outer ring surface of the soft gel is provided with an inclined annular protrusion part, the assembly hole is provided with a first bevel that expands outward, a second bevel of the annular protrusion part is in close contact with the first bevel, and a soft gel part that is concave inwardly or convex outwardly is provided between the annular protrusion part and the sealing ring.

8. The induction hob according to claim 3, wherein a soft gel for sealing is attached between an edge of the non-ferrous probe and an inner wall of the assembly hole, the edge of the non-ferrous probe is provided with a sealing groove, an inner ring surface of the soft gel is provided with a sealing ring, the sealing ring is snap-fitted into the sealing groove, an outer ring surface of the soft gel is provided with an inclined annular protrusion part, the assembly hole is provided with a first bevel that expands outward, a second bevel of the annular protrusion part is in close contact with the first bevel, and a soft gel part that is concave inwardly or convex outwardly is provided between the annular protrusion part and the sealing ring.

9. The induction hob according to claim 4, wherein a soft gel for sealing is attached between an edge of the non-ferrous probe and an inner wall of the assembly hole, the edge of the non-ferrous probe is provided with a sealing groove, an inner ring surface of the soft gel is provided with a sealing ring, the sealing ring is snap-fitted into the sealing groove, an outer ring surface of the soft gel is provided with an inclined annular protrusion part, the assembly hole is provided with a first bevel that expands outward, a second bevel of the annular protrusion part is in close contact with the first bevel, and a soft gel part that is concave inwardly or convex outwardly is provided between the annular protrusion part and the sealing ring.

10. The induction hob according to claim 5, wherein a soft gel for sealing is attached between an edge of the non-ferrous probe and an inner wall of the assembly hole, the edge of the non-ferrous probe is provided with a sealing groove, an inner ring surface of the soft gel is provided with a sealing ring, the sealing ring is snap-fitted into the sealing groove, an outer ring surface of the soft gel is provided with an inclined annular protrusion part, the assembly hole is provided with a first bevel that expands outward, a second bevel of the annular protrusion part is in close contact with the first bevel, and a soft gel part that is concave inwardly or convex outwardly is provided between the annular protrusion part and the sealing ring.

11. The induction hob according to claim 6, wherein restricting plates are provided on both sides of a top edge of the movable support respectively, the restricting plates on both sides upwardly support two lateral edges at bottom of the soft gel respectively, two lateral edges at bottom of the non-ferrous probe are provided with restricting openings respectively, and the restricting plates on both sides are in restricted fit with the restricting openings on both sides.

12. The induction hob according to claim 1, wherein a bottom edge of the non-ferrous probe is in a form of a downwardly extending cylinder, a top edge of the movable support is in a form of an upwardly extending cylinder, and a top of the movable support is sheathed into a bottom of the non-ferrous probe with snap-fit fastening.

13. The induction hob according to claim 2, wherein a bottom edge of the non-ferrous probe is in a form of a downwardly extending cylinder, a top edge of the movable support is in a form of an upwardly extending cylinder, and a top of the movable support is sheathed into a bottom of the non-ferrous probe with snap-fit fastening.

14. The induction hob according to claim 3, wherein a bottom edge of the non-ferrous probe is in a form of a downwardly extending cylinder, a top edge of the movable support is in a form of an upwardly extending cylinder, and a top of the movable support is sheathed into a bottom of the non-ferrous probe with snap-fit fastening.

15. The induction hob according to claim 4, wherein a bottom edge of the non-ferrous probe is in a form of a downwardly extending cylinder, a top edge of the movable support is in a form of an upwardly extending cylinder, and a top of the movable support is sheathed into a bottom of the non-ferrous probe with snap-fit fastening.

16. The induction hob according to claim 5, wherein a bottom edge of the non-ferrous probe is in a form of a downwardly extending cylinder, a top edge of the movable support is in a form of an upwardly extending cylinder, and a top of the movable support is sheathed into a bottom of the non-ferrous probe with snap-fit fastening.

17. The induction hob according to claim 1, wherein a coil support is provided between the bottom housing and the top housing, a shielding layer is provided between the coil support and the bottom housing, a center of the coil support is provided with an active hole, a bottom edge of the movable support is in a form of a downwardly extending cylinder, the bottom housing is provided with a cylindrical chamber extending upwardly, a bottom of the movable support passes through the active hole and is sheathed into a cylindrical chamber of the bottom housing, and the elastic member is elastically pressed against between the bottom of the movable support and the cylindrical chamber of the bottom housing.

18. The induction hob according to claim 2, wherein a coil support is provided between the bottom housing and the top housing, a shielding layer is provided between the coil support and the bottom housing, a center of the coil support is provided with an active hole, a bottom edge of the movable support is in a form of a downwardly extending cylinder, the bottom housing is provided with a cylindrical chamber extending upwardly, a bottom of the movable support passes through the active hole and is sheathed into a cylindrical chamber of the bottom housing, and the elastic member is elastically pressed against between the bottom of the movable support and the cylindrical chamber of the bottom housing.

19. The induction hob according to claim 3, wherein a coil support is provided between the bottom housing and the top housing, a shielding layer is provided between the coil support and the bottom housing, a center of the coil support is provided with an active hole, a bottom edge of the movable support is in a form of a downwardly extending cylinder, the bottom housing is provided with a cylindrical chamber extending upwardly, a bottom of the movable support passes through the active hole and is sheathed into a cylindrical chamber of the bottom housing, and the elastic member is elastically pressed against between the bottom of the movable support and the cylindrical chamber of the bottom housing.

20. The induction hob according to claim 1, wherein the movable support allows a travel of 3 mm±0.5 mm from top to bottom, the elastic member is a spring, the non-ferrous probe is a metallic probe that is non-ferrous, and the temperature sensor is an NTC temperature sensor.
